(19) United States
(12) Patent Application Publication
(10) Pub. No.: US 2016/0064429 A1
(43) Pub. Date: Mar. 3, 2016

(54) SOLID-STATE IMAGE SENSOR AND CAMERA

(71) Applicant: CANON KABUSHIKI KAISHA, Tokyo (JP)

(72) Inventors: Satoko Iida, Yokohama-shi (JP); Takanori Watanabe, Yamato-shi (JP)

(21) Appl. No.: 14/818,756

(22) Filed: Aug. 5, 2015

(30) Foreign Application Priority Data
Aug. 29, 2014 (JP) 2014-176219
Mar. 24, 2015 (JP) 2015-061665

(51) Int. Cl. H01L 27/146; H04N 5/355; H04N 5/335

(52) U.S. Cl. CPC H01L 27/1461; H01L 27/14616; H04N 5/335; H04N 5/3559

(57) ABSTRACT

A solid-state image sensor is provided. The sensor includes a semiconductor region having a first conductivity type, and a charge accumulation portion having a second conductivity type. The semiconductor region includes a first semiconductor region, and a second semiconductor region formed below the first semiconductor region and having an impurity concentration higher than that of the first semiconductor region. The charge accumulation portion has a side and a bottom covered with the semiconductor region, and includes at least three regions arranged along a depth direction. A first region formed in a shallowest position has a width larger than that of each of the at least three regions. An impurity concentration of a second region formed in a deepest position is higher than that of each region between the first and second region of the at least three regions.

### BACKGROUND OF THE INVENTION

1. Field of the Invention

The present invention relates to a solid-state image sensor and camera.

2. Description of the Related Art

Japanese Patent Laid-Open No. 2002-164529 describes a structure which suppresses a decrease in sensitivity by compensating for a reduction in saturated charge quantity of a signal charge in a charge accumulation portion in a solid-state image sensor having a downsized pixel region, and a method of manufacturing the structure. In this structure, a plurality of charge accumulation portions are stacked in the pixel region in the depth direction of a substrate, and an impurity concentration is decreased toward the depths of the substrate.

### SUMMARY OF THE INVENTION

The present inventors have found that the structure described in Japanese Patent Laid-Open No. 2002-164529 has an impurity concentration distribution which is inefficient for increasing the saturated charge quantity of a signal charge to be accumulated. This makes the security of the saturated charge quantity and the suppression of a decrease in sensitivity insufficient. An embodiment of the present invention provides a technique of increasing a saturated charge quantity in a charge accumulation portion of a solid-state image sensor, and increasing the sensitivity of the sensor.

According to some embodiments, a solid-state image sensor comprising a substrate including a semiconductor region having a first conductivity type, and a charge accumulation portion having a second conductivity type opposite to the first conductivity type and configured to accumulate an electric charge generated by photoelectric conversion, wherein the semiconductor region includes a first semiconductor region, and a second semiconductor region formed below the first semiconductor region and having an impurity concentration higher than that of the first semiconductor region, the charge accumulation portion has a side and a bottom covered with the semiconductor region, and includes at least three regions arranged along a depth direction of the substrate, a first region formed in a shallowest position of the at least three regions has a width larger than that of each of the at least three regions except for the first region, in a direction parallel to a surface of the substrate, and an impurity concentration of a second region formed in a deepest position of the at least three regions is higher than that of each region between the first region and the second region of the at least three regions, is provided.

According to some other embodiments, a solid-state image sensor comprising a substrate including a semiconductor region having a first conductivity type, and a charge accumulation portion brought into contact with the semiconductor region, having a second conductivity type opposite to the first conductivity type, and configured to accumulate an electric charge generated by photoelectric conversion, wherein an impurity concentration distribution of the semiconductor region in a depth direction of the substrate includes a first part, and a second part below the first part and having an impurity concentration higher than that of the first part, an impurity concentration distribution of the charge accumulation portion in the depth direction has at least three peaks, and an impurity concentration of a peak in a deepest position of the at least three peaks is higher than that of one of the at least three peaks except for a peak in a shallowest position and the peak in the deepest position, is provided.

According to some other embodiments, a solid-state image sensor comprising a substrate including a semiconductor region having a first conductivity type, and a charge accumulation portion having a second conductivity type opposite to the first conductivity type and configured to accumulate an electric charge generated by photoelectric conversion, wherein the semiconductor region includes a first semiconductor region, and a second semiconductor region formed below the first semiconductor region and having an impurity concentration higher than that of the first semiconductor region, the charge accumulation portion includes at least a first region and a second region arranged in this order from a surface of the substrate along a depth direction of the substrate, and a third region formed between the first region and the second region, the first region has a width larger than those of the second region and the third region in a direction parallel to the surface, and an impurity concentration of the second region is higher than that of the third region, is provided.

According to some other embodiments, a solid-state image sensor comprising a substrate including a semiconductor region having a first conductivity type, and a charge accumulation portion having a second conductivity type opposite to the first conductivity type and configured to accumulate an electric charge generated by photoelectric conversion, wherein an impurity concentration of the semiconductor region at a first part of the semiconductor region is lower than an impurity concentration of the semiconductor region at a second part of the semiconductor region, the second part being provided below the first part, a first length of the charge accumulation portion along a first line which is parallel to a surface of the substrate and is passing at a first point within the charge accumulation portion is longer than a second length of the charge accumulation portion along a second line which is parallel to the surface and is passing at a second point within the charge accumulation portion and than a third length of the charge accumulation portion along a third line which is parallel to the surface and is passing at a third point within the charge accumulation portion, the first point, the third point and the second point are arranged along a depth direction in this order from the surface, and an impurity concentration of the charge accumulation portion at the second point is higher than an impurity concentration of the accumulation portion at the third point, is provided.

According to some other embodiments, a camera comprising a solid-state image sensor and a signal processing unit, wherein the solid-state image sensor comprises a substrate including a semiconductor region having a first conductivity type, and a charge accumulation portion having a second conductivity type opposite to the first conductivity type and configured to accumulate an electric charge generated by photoelectric conversion, the semiconductor region includes a first semiconductor region, and a second semiconductor region formed below the first semiconductor region and having an impurity concentration higher than that of the first semiconductor region, the charge accumulation portion has a side and a bottom covered with the semiconductor region, and includes at least three regions arranged along a depth direction of the substrate, a first region formed in a shallowest position of the at least three regions has a width larger than that of each of the at least three regions except for the first region, in a direction parallel to a surface of the substrate, an impurity concentration of a second region formed in a deepest position of the at least three regions is higher than that of each region between the first region and the second region of the at least three regions; and the signal processing unit configured to process a signal obtained by the solid-state image sensor, is provided.

Further features of the present invention will become apparent from the following description of exemplary embodiments (with reference to the attached drawings).

### BRIEF DESCRIPTION OF THE DRAWINGS

FIG. 1 is a sectional view of a solid-state image sensor according to an embodiment of the present invention;

FIGS. 2A to 2G are sectional views for explaining a method of manufacturing the solid-state image sensor shown in FIG. 1;

FIGS. 3A and 3B are sectional views showing a modification of a charge accumulation portion of the solid-state image sensor shown in FIG. 1;

FIGS. 4A and 4B are sectional views showing another modification of the charge accumulation portion of the solid-state image sensor shown in FIG. 1;

FIGS. 5A and 5B are views showing an impurity concentration distribution and potential distribution in the solid-state image sensor shown in FIG. 1;

FIG. 6 is a sectional view of a solid-state image sensor according to an embodiment of the present invention;

FIGS. 7A and 7B are views showing an impurity concentration distribution and potential distribution in the solid-state image sensor shown in FIG. 6;

FIGS. 8A and 8B are views showing an impurity concentration distribution and potential distribution in a solid-state image sensor according to an embodiment of the present invention;

FIG. 9 is a sectional view of a solid-state image sensor according to an embodiment of the present invention;

FIGS. 10A and 10B are views showing an impurity concentration distribution and potential distribution in the solid-state image sensor shown in FIG. 9;

FIG. 11 is a sectional view of a solid-state image sensor according to an embodiment of the present invention;

FIGS. 12A and 12B are views showing impurity concentration distributions in the solid-state image sensor shown in FIG. 11;

FIGS. 13A and 13B are sectional views of solid-state image sensors according to an embodiment of the present invention; and

FIGS. 14A and 14B are views showing an impurity concentration distribution and potential distribution in a solid-state image sensor according to an embodiment of the present invention.

### DESCRIPTION OF THE EMBODIMENTS

Practical embodiments of a solid-state image sensor according to the present invention will be explained below with reference to the accompanying drawings. Solid-state image sensors manufactured in the following embodiments are so-called CMOS solid-state image sensors. However, the present invention is not limited to these embodiments. For example, the present invention is also applicable to a CCD solid-state image sensor. In addition, the following embodiments handle a case in which a signal charge is of an electron. When the signal charge is of a hole, the conductivity types of impurity regions to be explained below need only be switched.

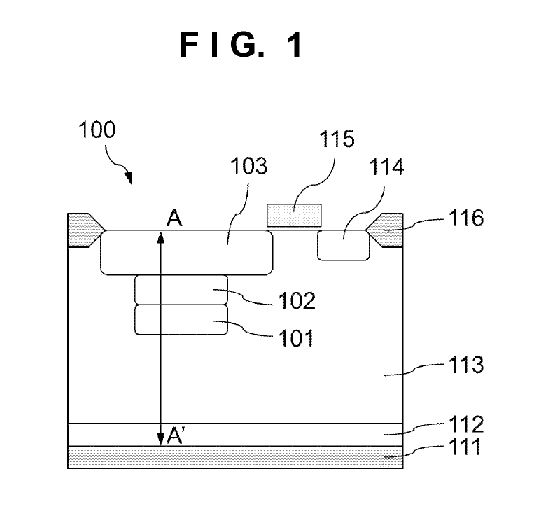

The structure and manufacturing method of a solid-state image sensor according to an embodiment of the present invention will be explained with reference to FIGS. 1 to 5. FIG. 1 is a sectional view schematically showing an arrangement example of a photoelectric converter formed in one pixel of a solid-state image sensor 100 according to a first embodiment of the present invention. The solid-state image sensor 100 according to this embodiment includes a semiconductor substrate 111 having an n-type as a second conductivity type. The semiconductor substrate 111 of the solid-state image sensor 100 includes an n-type charge accumulation portion for accumulating an electric charge generated by photoelectric conversion, a well layer 113 which is a first semiconductor region having a p-type as a first conductivity type, and a floating diffusion (FD) portion 114. The charge accumulation portion includes n-type charge accumulation regions 101, 102, and 103. Of the three stacked charge accumulation regions 101, 102, and 103, the charge accumulation region 103 as a first region in the direction of depth of the semiconductor substrate 111 is positioned in the shallowest place, and the charge accumulation region 101 as a second region is positioned in the deepest place. The charge accumulation region 102 is positioned between the charge accumulation region 101 and the charge accumulation region 103. The width (the length in a direction parallel to the surface of the semiconductor substrate 111; the same shall apply hereinafter) of the charge accumulation region 103 is larger than that of the charge accumulation regions 101 and 102. An element isolation portion 116 is also formed to electrically isolate individual elements in the solid-state image sensor 100. A p-type overflow barrier layer 112 as a second semiconductor region having an impurity concentration higher than that in the well layer 113 is formed below the well layer 113. As shown in FIG. 1, the side surfaces and bottom surface of the charge accumulation portion are covered with the well layer 113 and overflow barrier layer 112.

The n-type charge accumulation portion and p-type well layer 113 form a p-n junction, thereby forming a p-n photodiode. A gate electrode 115 is formed on a gate insulating film (not shown) on the well layer 113 of the semiconductor substrate 111. If an ON voltage is applied, the gate electrode 115 transfers a signal charge accumulated in the charge accumulation portion to the FD portion 114. The FD portion 114 forms an output node for an amplification portion (not shown). A signal corresponding to the fluctuation amount of the potential caused by the electric charge transferred to the FD portion 114 is read out as a pixel signal from this output node. The overflow barrier layer 112 prevents leakage of the accumulated signal charge to the semiconductor substrate 111.

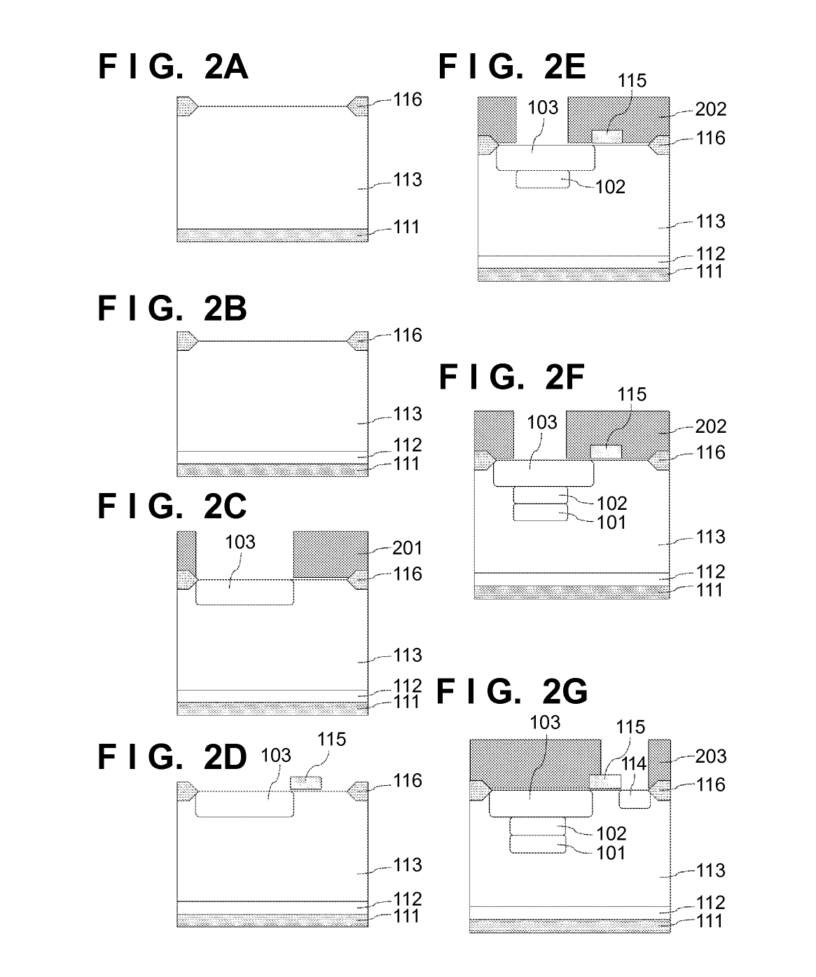

Next, a method of manufacturing the photoelectric converter formed in one pixel of the solid-state image sensor 100 of this embodiment will be explained with reference to FIGS. 2A to 2G. FIG. 2A shows a state in which a semiconductor substrate 111 having an element isolation portion 116 is prepared, and a well layer 113 is formed by implanting a p-type impurity into the semiconductor substrate 111. An overflow barrier layer 112 is formed by implanting a p-type impurity into the semiconductor substrate 111 at a high energy and high concentration. FIG. 2B shows this state. When forming the overflow barrier layer 112 in this embodiment, implantation is performed by using an implantation energy of, for example, 2.5 MeV such that the impurity concentration in the overflow barrier layer 112 is 5×10¹⁷ cm⁻³. Then, an n-type impurity is implanted by using a mask pattern 201 having an opening over a portion of the well layer 113, thereby forming an uppermost charge accumulation region 103 positioned in the shallowest region of the charge accumulation portion of the well layer 113. When forming the charge accumulation region 103, implantation is performed by using an implantation energy of, for example, 500 keV such that the impurity concentration in the uppermost charge accumulation region 103 is 5×10¹⁶ cm⁻³. FIG. 2C shows this state. Subsequently, a gate electrode 115 is formed as shown in FIG. 2D. The gate electrode 115 is formed in a position covering a region adjacent to the charge accumulation region 103.

After the formation of the gate electrode 115, an n-type impurity is implanted by using a mask pattern 202 having an opening over the charge accumulation region 103, thereby forming charge accumulation regions 102 and 101 in the well layer 113. The opening region of the mask pattern 202 is narrower than that of the mask pattern 201 for forming the charge accumulation region 103. The width of the charge accumulation regions 102 and 101 is smaller than that of the charge accumulation region 103. By decreasing the widths of the charge accumulation regions 102 and 101 formed in deep positions in the depth direction of the semiconductor substrate 111, it becomes possible to facilitate depletion when transferring an electric charge, thereby maintaining the transfer efficiency. FIG. 2E shows a state in which the charge accumulation region 102 is formed, and FIG. 2F shows a state in which the charge accumulation regions 101 and 102 are formed. It is possible to form either the charge accumulation region 101 or charge accumulation region 102 first. Impurity implantation for forming the lowermost charge accumulation region 101 in the deepest position of the charge accumulation portion and impurity implantation for forming the charge accumulation region 102 between the uppermost charge accumulation region 103 and lowermost charge accumulation region 101 are performed under, for example, the following conditions. To form the charge accumulation region 102, implantation is performed by using an implantation energy of 600 keV such that the impurity concentration is 1×10¹⁷ cm⁻³. To form the charge accumulation region 101, implantation is performed by using an implantation energy of 700 keV such that the impurity concentration is 2×10¹⁷ cm⁻³. In the charge accumulation region 101 thus formed in the lowermost portion by the highest implantation energy among the charge accumulation regions 101, 102, and 103, impurity implantation is performed a plurality of times so that the impurity concentration becomes highest. More specifically, the amount (dose) of impurity to be implanted is changed for each energy. The amount of impurity to be implanted by impurity implantation for forming the charge accumulation region 101 is larger than the amount of impurity to be implanted by impurity implantation for forming the charge accumulation region 102. In addition, the amount of impurity to be implanted by impurity implantation for forming the charge accumulation region 101 is larger than the amount of impurity to be implanted by impurity implantation for forming the charge accumulation region 103. The amount of impurity to be implanted is represented by the number of impurity ions to be implanted per 1 cm². Also, in this embodiment, the charge accumulation regions 101 and 102 are formed by using the same mask pattern 202. This makes it possible to reduce the number of masks and the number of manufacturing steps.

Finally, as shown in FIG. 2G, an FD portion 114 is formed by using a mask pattern 203. The mask pattern 203 has an opening over a region of the well layer 113, which is opposite to the charge accumulation region 101 with respect to the gate electrode 115. The mask pattern 203 may also have openings over portions of the gate electrode 115 and element isolation portion 116 adjacent to the formation region of the FD portion 114. In this case, the gate electrode 115 and element isolation portion 116 also function as masks. The FD portion 114 is formed by implanting an n-type impurity through the opening of the mask pattern 203.

The photoelectric converter in the pixel of the solid-state image sensor 100 shown in FIG. 1 is formed by the above-described steps. However, the present invention is not limited to this manufacturing method, and the constituent elements of the photoelectric converter of the solid-state image sensor 100 need only be formed. The manufacturing method of the present invention is not limited to these steps. For example, it is also possible to add a step of implanting an impurity into the peripheral portion of the gate electrode 115 as needed, in order to prevent a transfer defect when transferring an electric charge accumulated in the charge accumulation portion to the FD portion. As this additional step, it is possible to form a mask pattern so as to form an n-type impurity region below the gate electrode 115 and implant an n-type impurity, or obliquely implant an n-type impurity into the substrate around the gate electrode 115.

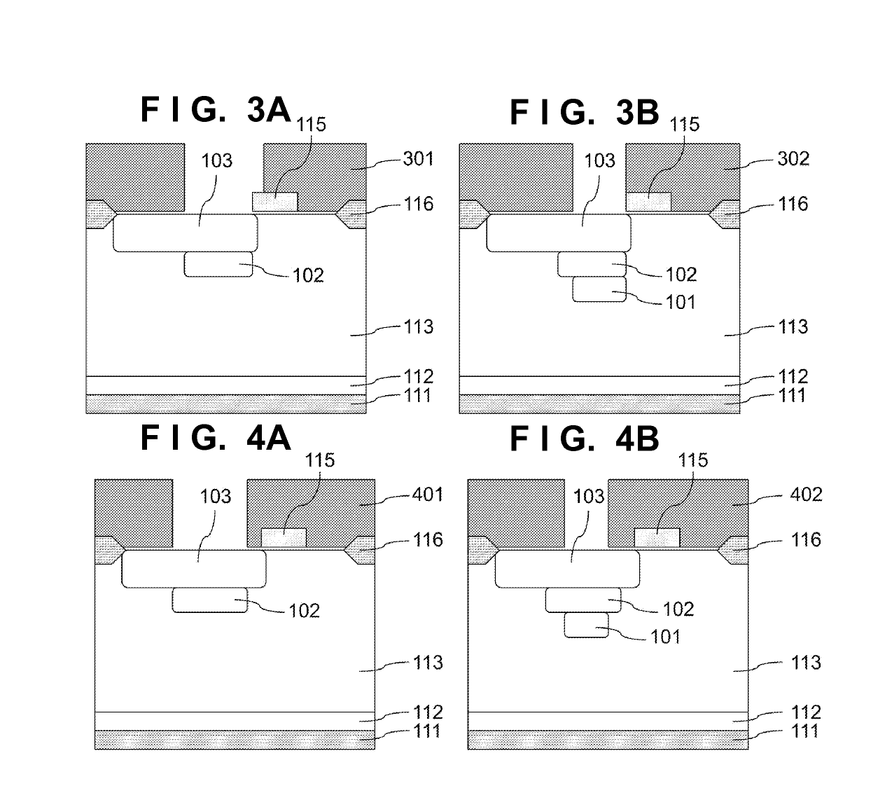

Furthermore, in the solid-state image sensor 100, the charge accumulation regions 101 and 102 are formed near the center of the charge accumulation region 103 in a planar view with respect to the surface of the semiconductor substrate 111. However, the formation position of the charge accumulation regions 101 and 102 is not limited to this. As shown in FIG. 3A, the charge accumulation region 102 is formed by using a mask pattern 301 having an opening over a portion of the charge accumulation region 103, which is adjacent to the gate electrode 115. Then, as shown in FIG. 3B, the charge accumulation region 101 is formed by using a mask pattern 302 having an opening smaller than that of the mask pattern 301, over a portion of the charge accumulation region 103, which is adjacent to the gate electrode 115. By using the mask patterns 301 and 302 as described above, the width of the charge accumulation region 101 becomes smaller than that of the charge accumulation region 102. In this case, the mask patterns 301 and 302 may further have openings above the gate electrode 115. A transfer defect hardly occurs when the charge accumulation regions 101 and 102 are formed near the gate electrode 115 by using the mask patterns 301 and 302.

Also, as shown in FIG. 4A, the charge accumulation region 102 is formed by using a mask pattern 401 having an opening over a portion of the charge accumulation region 103. Then, as shown in FIG. 4B, the charge accumulation region 101 is formed by using a mask pattern 402 having an opening smaller than that of the mask pattern 401, over a portion of the charge accumulation region 103. By using the mask patterns 401 and 402 as described above, the width of the charge accumulation region 101 becomes smaller than that of the charge accumulation region 102. Thus, the charge accumulation regions 101 and 102 may also be formed by using different mask patterns. The number of steps increases if using different mask patterns. However, by gradually decreasing the widths of the charge accumulation regions 102 and 101 formed in the deep positions in the depth direction of the semiconductor substrate 111, it becomes possible to facilitate depleting the charge accumulation portion when transferring an electric charge, thereby maintaining the transfer efficiency. Also, in a region where an impurity is deeply implanted at a high energy, the implanted impurity readily diffuses in a wide area due to channeling or the like. To prevent this, the widths of the openings of the mask patterns for forming the charge accumulation regions 103, 102, and 101 are gradually decreased in this order. Consequently, the width of the charge accumulation region 102 may be made larger than that of the charge accumulation region 101.

The rest of the arrangement of the solid-state image sensor except for the photoelectric converter can be formed by using the existing methods, so a detailed explanation thereof will be omitted. The solid-state image sensor 100 is manufactured by performing these steps.

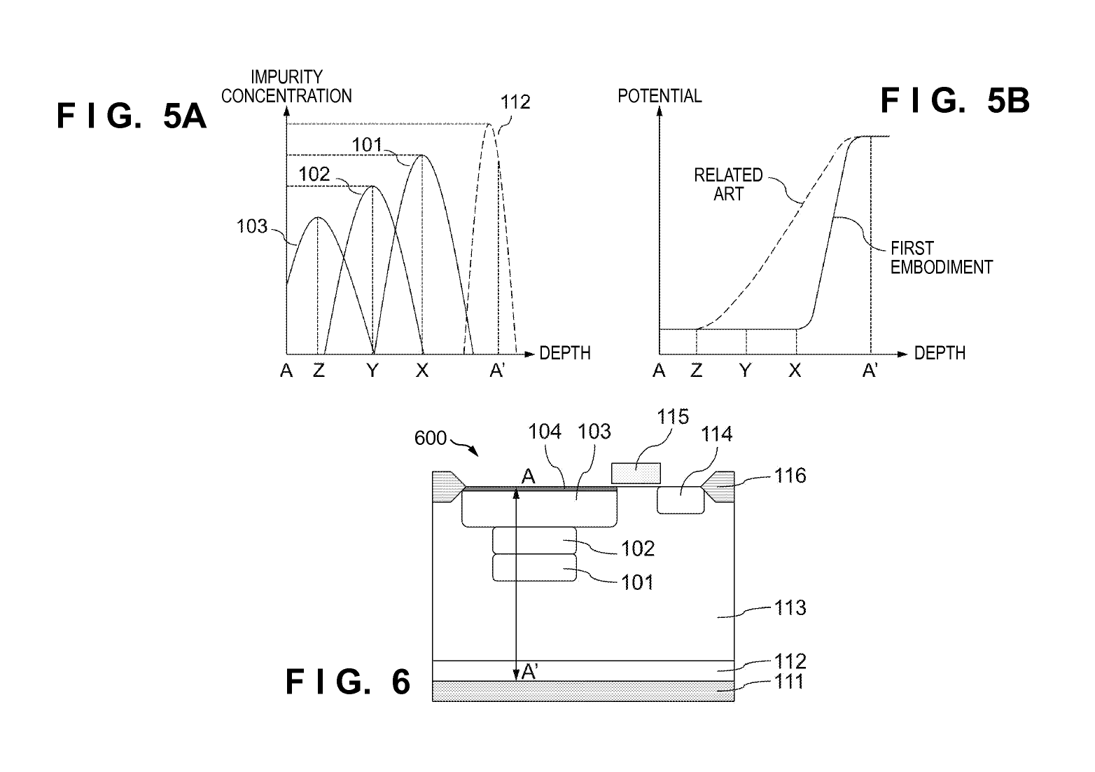

FIGS. 5A and 5B show an impurity concentration distribution and potential distribution in an A-A′ section of the solid-state image sensor 100 shown in FIG. 1. The abscissa axis indicates a position in the depth direction in the A-A′ section. X, Y, and Z represent the peak positions of concentrations when implanting impurities into the charge accumulation portion. In FIG. 5A, the ordinate axis represents the concentration of an n-type impurity in the charge accumulation portion, and the concentration of a p-type impurity in the overflow barrier layer 112. In FIG. 5B, the ordinate axis represents a potential formed by the charge accumulation portion, well layer 113, and overflow barrier layer 112.

As shown in FIG. 5A, the three charge accumulation regions 101, 102, and 103 each have one impurity concentration peak position when impurity implantation is performed. Thus, a region formed by performing impurity implantation once is used as, for example, a charge accumulation region or impurity region. Also, this region may extend in a wide area in a heating step after that. In this case, a range within which the concentration is a half-width of the impurity peak concentration may be used as each region. A range within which the concentration is one order of magnitude lower than the impurity peak concentration may also be used as each region. As shown in FIG. 5A, the charge accumulation regions 101 and 102 are formed in positions deeper than the charge accumulation region 103, and this makes it possible to collect and accumulate a signal charge generated in a deep portion of the semiconductor substrate 111, and increase the collection efficiency. In addition, as described in the manufacturing method of this embodiment, the charge accumulation region 101 in the deepest position among the three charge accumulation regions has the highest impurity concentration when compared to the charge accumulation regions in positions other than the deepest position, and the charge accumulation region 103 in the shallowest position has the lowest impurity concentration. Furthermore, as for the peak height of the impurity concentration when impurity implantation is performed, the peak for forming the charge accumulation region 101 in the deepest position is higher than the impurity concentration peaks other than this peak.

The effects of this embodiment will now be explained. As shown in FIG. 5B, the impurity concentration of the charge accumulation region 101 in the deepest position is made higher than those of the charge accumulation regions other than the region in the deepest position. This forms a potential distribution which functions as a charge accumulation region having a large capacity to a deeper position in the semiconductor substrate 111, from the relationship with the impurity concentration of the overflow barrier layer 112. A potential distribution indicated by the solid line is the potential distribution according to this embodiment. A potential distribution indicated by the dotted line is a potential distribution obtained by using the related art. This potential distribution obtained by using the related art is a potential distribution if the charge accumulation region 103 is the only charge accumulation region or if the impurity concentration in the charge accumulation region decreases toward a deeper position in the depth direction of the substrate. The saturated charge quantity of the charge accumulation region is determined by the product of the depletion layer capacity and potential difference between the n-type impurity region forming the charge accumulation portion, and the p-type impurity regions forming the well layer 113 and overflow barrier layer 112. In this embodiment, a region having a large potential difference can be formed to a deeper position in the semiconductor substrate 111 by making the impurity concentration of the lowermost charge accumulation region 101 higher than those of the charge accumulation regions 102 and 103. This makes it possible to accumulate a signal charge larger than that of the conventional potential distribution, thereby increasing the saturated charge quantity. It is also possible to increase the sensitivity because a high potential barrier can be formed in a deep position of the semiconductor substrate 111 as shown in FIG. 5B. Furthermore, as shown in FIG. 1, the width of the charge accumulation regions 101 and 102 in the sectional direction is smaller than that of the charge accumulation region 103 in the sectional direction. Since the narrow charge accumulation regions 101 and 102 extend in a deep region of the semiconductor substrate 111, it is possible to increase the saturated charge quantity and sensitivity while maintaining the transfer efficiency.

The potential distribution suited to accumulating a larger amount of electric charge to a deep position of the semiconductor substrate 111 may not always have a potential gradient which moves the accumulated charge in the direction of the substrate surface. For example, as shown in FIG. 5B, the potential may have a flat region. As described above, the saturated charge quantity is determined by the product of the depletion layer capacity and potential difference. Therefore, a large charge accumulation amount can be obtained when the potential distribution has a flat portion. To increase the saturated charge quantity, it is important to secure a wide large-potential-difference region. Also, even if the internal potential of the charge accumulation portion has no gradient which moves the electric charge to the substrate surface, a concentration gradient is produced by a signal charge during charge transfer. The accumulated signal charge is diffused by this concentration gradient, and transferred to the substrate surface. The potential of the FD portion 114 as the transfer destination of the signal charge is lower than that of the charge accumulation portion. When an ON voltage is applied to the gate electrode 115, therefore, a signal charge existing in that portion of the charge accumulation portion, which is close to the FD portion 114, can move to the FD portion 114 at a predetermined ratio (probability). Meanwhile, the probability that the electric charge moves from the FD portion 114 to the charge accumulation portion is low because there is a potential difference between the charge accumulation portion and FD portion 114. As a consequence, the amount of signal charge in that portion of the charge accumulation region 103, which is close to the FD portion 114, in the charge accumulation portion reduces, thereby producing a concentration gradient inside the charge accumulation portion. By this concentration gradient, the signal charge diffuses inside the charge accumulation portion so as to approach the FD portion 114. However, if the potential has a gradient which moves an electric charge to a deep position in the semiconductor substrate 111, the electric charge hardly moves to the surface side, so transfer takes a long time, and this causes an image lag. The impurity concentration and position of the charge accumulation region 101 in the deepest position need only be determined such that the potential has at least no gradient by which the electric charge moves to a deep position in the semiconductor substrate 111.

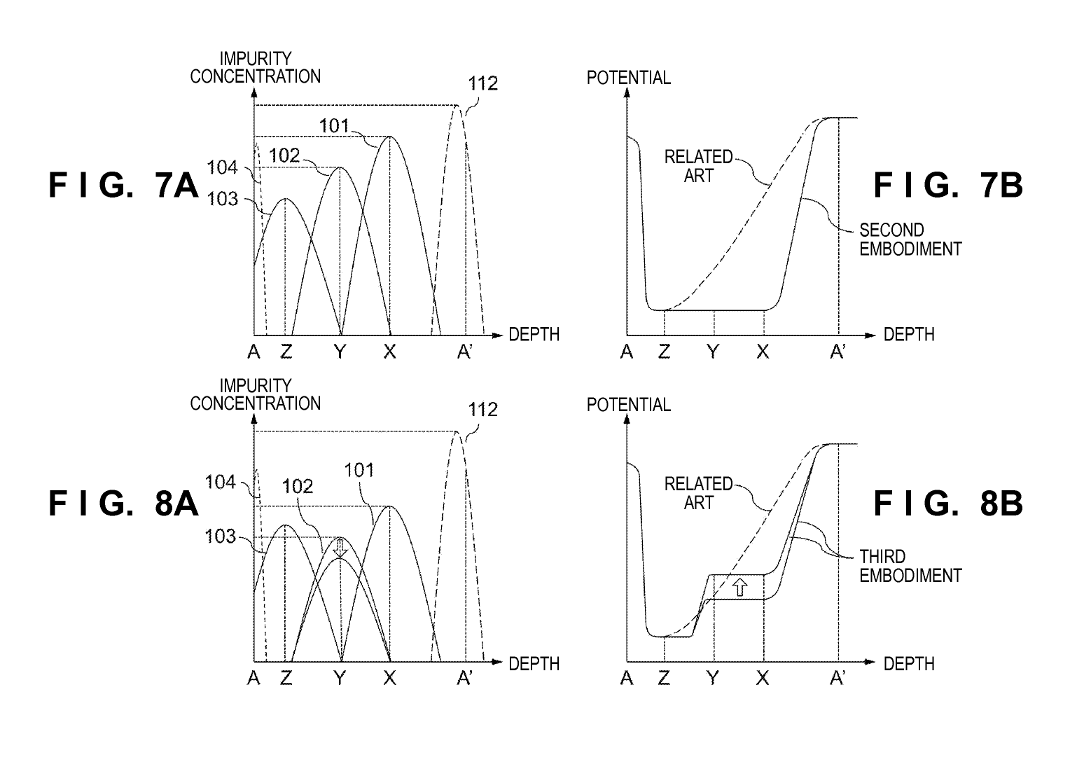

The structure and manufacturing method of a solid-state image sensor 600 according to a second embodiment of the present invention will be explained with reference to FIGS. 6, 7A, and 7B. FIG. 6 is a sectional view schematically showing an arrangement example of a photoelectric converter formed in one pixel of the solid-state image sensor 600 according to the second embodiment of the present invention. Referring to FIG. 6, the solid-state image sensor 600 according to this embodiment differs from the solid-state image sensor 100 according to the first embodiment in that a p-type impurity region 104 as a third semiconductor region is formed on a charge accumulation region 103 in the shallowest position. The rest of the arrangement can be the same. Therefore, a repetitive explanation of the same constituent elements as those of the solid-state image sensor 100 will be omitted. The impurity region 104 is so formed as to space the charge accumulation region 103 apart from the pixel surface. This reduces a dark current component.

A method of manufacturing the photoelectric converter formed in one pixel of the solid-state image sensor 600 will now be explained. The solid-state image sensor 600 is formed like the solid-state image sensor 100. That is, after charge accumulation regions 101, 102, and 103 are formed, a p-type impurity is implanted by using a mask pattern having an opening over the charge accumulation region 103. This mask pattern may also have an opening over a portion of a gate electrode 115 adjacent to the charge accumulation region 103 and an opening over a portion of an element isolation portion 116. In this case, the gate electrode 115 and element isolation portion 116 also function as masks. Other steps can be the same as those of the solid-state image sensor 100. In addition, the present invention is not limited to this manufacturing method, and the constituent elements of the photoelectric converter of the solid-state image sensor 600 need only be formed.

FIGS. 7A and 7B show an impurity concentration distribution and potential distribution in an A-A′ section of the solid-state image sensor 600 shown in FIG. 6. Compared to the concentration obtained when implanting an impurity into the solid-state image sensor 100 shown in FIG. 5A, the concentration obtained when implanting an impurity into the solid-state image sensor 600 shown in FIG. 7A has a region formed in the substrate surface by the impurity region 104 and having a high p-type impurity concentration. Also, as shown in FIG. 7B, the impurity region 104 forms a potential barrier on the surface side of the substrate. This suppresses the generation of a dark current by spacing the charge accumulation region apart from the substrate surface. A region having a large potential difference can be formed to a deep position in a semiconductor substrate 111 by making the impurity concentration of the charge accumulation region 101 in the deepest position higher than those of the charge accumulation regions 102 and 103, in this embodiment as well. It is also possible to form a high potential barrier in a deep position in the semiconductor substrate 111. Accordingly, the solid-state image sensor 600 can also achieve the same effects as those of the solid-state image sensor 100 described above.

The structure and manufacturing method of a solid-state image sensor according to a third embodiment of the present invention will be explained with reference to FIGS. 8A and 8B. The solid-state image sensor according to this embodiment differs from the solid-state image sensor 600 according to the second embodiment in that the impurity concentration of a charge accumulation region 102 is made lower than that of a charge accumulation region 103 in the shallowest position, and the rest of the arrangement can be the same. Therefore, the sectional structure of the solid-state image sensor according to this embodiment is the same as that of the solid-state image sensor 600. Accordingly, a repetitive explanation of the constituent elements will be omitted.

A method of manufacturing a photoelectric converter formed in one pixel of the solid-state image sensor of this embodiment will now be explained. The solid-state image sensor of this embodiment can be the same as the solid-state image sensor 600 except for the impurity implantation conditions of charge accumulation regions 101 and 102. Implantation for forming the charge accumulation regions 101 and 102 is performed under, for example, the following conditions. To form the charge accumulation region 102, implantation is performed by using an implantation energy of 600 keV such that the impurity concentration is 2×10¹⁶ cm⁻³. To form the charge accumulation region 101, implantation is performed by using an implantation energy of 700 keV such that the impurity concentration in a charge accumulation region in the deepest position is 1×10¹⁷ cm⁻³. In this embodiment as described above, the charge accumulation region 102 is so formed that the impurity concentration becomes lower than that of the charge accumulation region 103 in the shallowest position. Also, impurity implantation is performed such that the impurity concentration in the charge accumulation region 101 formed in the deepest position is highest among the charge accumulation regions 101, 102, and 103, in this embodiment as well. Other steps can be the same as those of the solid-state image sensor 600. Furthermore, the present invention is not limited to this manufacturing method, and the constituent elements of the photoelectric converter of the solid-state image sensor of this embodiment need only be formed.

FIGS. 8A and 8B show an impurity concentration distribution and potential distribution in an A-A′ section of the solid-state image sensor of this embodiment having the same structure as that of the solid-state image sensor 600 shown in FIG. 6. As shown in FIG. 8A, the impurity concentration of the charge accumulation region 102 is lower than that of the charge accumulation region 103. As indicated by the potential distribution shown in FIG. 8B, therefore, a potential difference is produced between the uppermost charge accumulation region 103 close to the substrate surface and the charge accumulation region 102. In addition, as shown in FIG. 8B, the potential distribution can be changed by changing the impurity concentration in the charge accumulation region 102. For example, when the impurity concentration in the charge accumulation region 102 is decreased, a potential height between depths Y and X increases.

By thus making the impurity concentration of the charge accumulation region 102 lower than that of the charge accumulation region 103, an effect of transferring a signal charge accumulated in the charge accumulation regions 101 and 102 as deep regions in the semiconductor substrate 111 to the substrate surface within a short time is obtained. Also, the impurity concentration of the charge accumulation region 101 in the deepest position is made higher than those of the charge accumulation regions 102 and 103, in this embodiment as well. This makes it possible to form a region having a large potential difference to a deep position in the semiconductor substrate 111, thereby forming a high potential barrier in the deep position. Accordingly, the same effects as those of the solid-state image sensor 600 described above can be obtained by the solid-state image sensor of this embodiment as well.

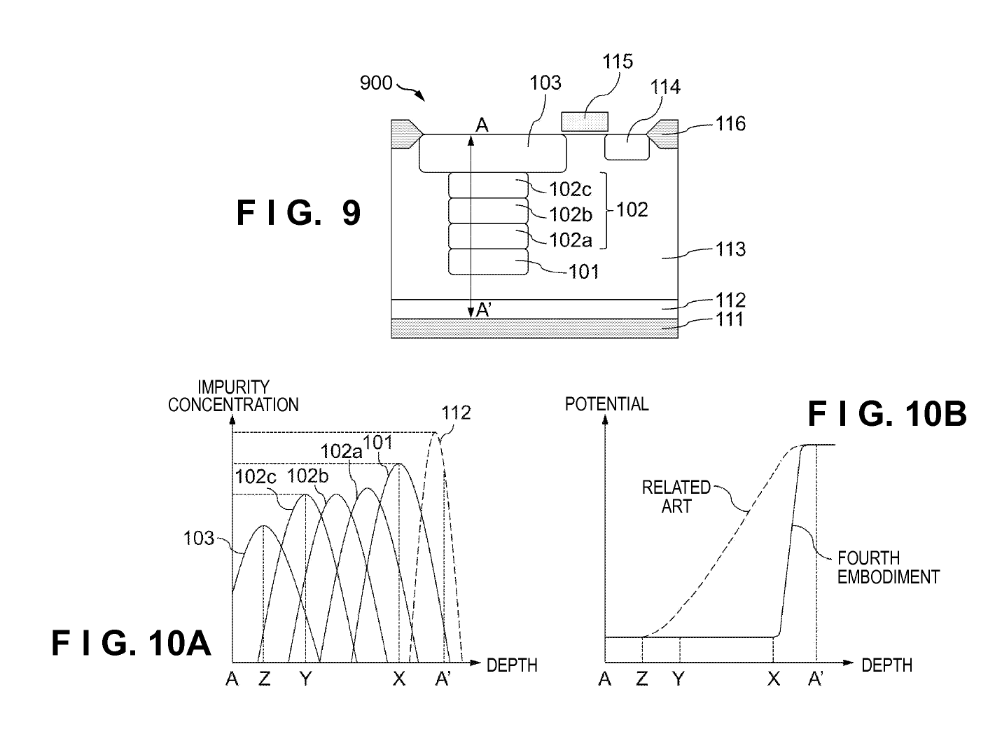

The structure and manufacturing method of a solid-state image sensor 900 according to a fourth embodiment of the present invention will be explained with reference to FIGS. 9, 10A, and 10B. FIG. 9 is a sectional view schematically showing an arrangement example of a photoelectric converter formed in one pixel of the solid-state image sensor 900 according to the fourth embodiment of the present invention. The solid-state image sensor 900 according to this embodiment differs from the solid-state image sensor 100 according to the first embodiment in that a charge accumulation region 102 including a plurality of layers is formed between a charge accumulation region 103 in the shallowest position and a charge accumulation region 101 in the deepest position. The rest of the arrangement can be the same. Therefore, a repetitive explanation of the same constituent elements as those of the solid-state image sensor 100 will be omitted. In this embodiment, the charge accumulation region 102 includes three layers of charge accumulation regions 102a, 102b, and 102c.

A method of manufacturing a photoelectric converter formed in one pixel of the solid-state image sensor 900 will now be explained. The solid-state image sensor 900 can be the same as the solid-state image sensor 100 except for the impurity implantation conditions of the charge accumulation region 102. When forming the charge accumulation region 102, implantation is performed such that the impurity concentration of each region is constant or the impurity concentration is higher a deeper region of the substrate. The charge accumulation region 102a may have an impurity concentration higher than those of the charge accumulation regions 102b and 102c. Also, impurity implantation is so performed that the charge accumulation region 101 formed in the deepest position has the highest impurity concentration among the charge accumulation regions 101, 102, and 103, and the charge accumulation region 103 in the shallowest position has the lowest impurity concentration, in this embodiment as well. Other steps can be the same as those of the solid-state image sensor 100. In addition, the present invention is not limited to this manufacturing method, and the constituent elements of the photoelectric converter of the solid-state image sensor of this embodiment need only be formed. Furthermore, in this embodiment, the charge accumulation region 102 has three impurity concentration peaks when an impurity is implanted. However, the number of peaks may also be two or four or more. That is, it is possible to appropriately design the peaks.

FIGS. 10A and 10B show an impurity concentration distribution and potential distribution in an A-A′ section of the solid-state image sensor 900 shown in FIG. 9. The concentration of the solid-state image sensor 900 shown in FIG. 10A when an impurity is implanted includes five n-type impurity concentration peaks of the charge accumulation region 101, the charge accumulation regions 102a, 102b, and 102c of the charge accumulation region 102, and the charge accumulation region 103. Also, a position X of the peak of the implantation dose when an impurity is implanted into the charge accumulation region 101 is formed in a deep position of the semiconductor substrate 111. A region having a large potential difference can be formed to a deep position in the semiconductor substrate 111 by making the impurity concentration of the charge accumulation region 101 in the deepest position higher than those of the charge accumulation regions 102 and 103, in this embodiment as well. Accordingly, the same effects as those of the solid-state image sensor 100 described above are obtained by the solid-state image sensor 900 as well. Furthermore, as shown in FIG. 10B, the position X of the impurity concentration peak of the charge accumulation region 101 is formed in a deeper position of the semiconductor substrate 111 than that in the solid-state image sensor 100. This makes it possible to accumulate more signal charge and further increase the saturated charge quantity.

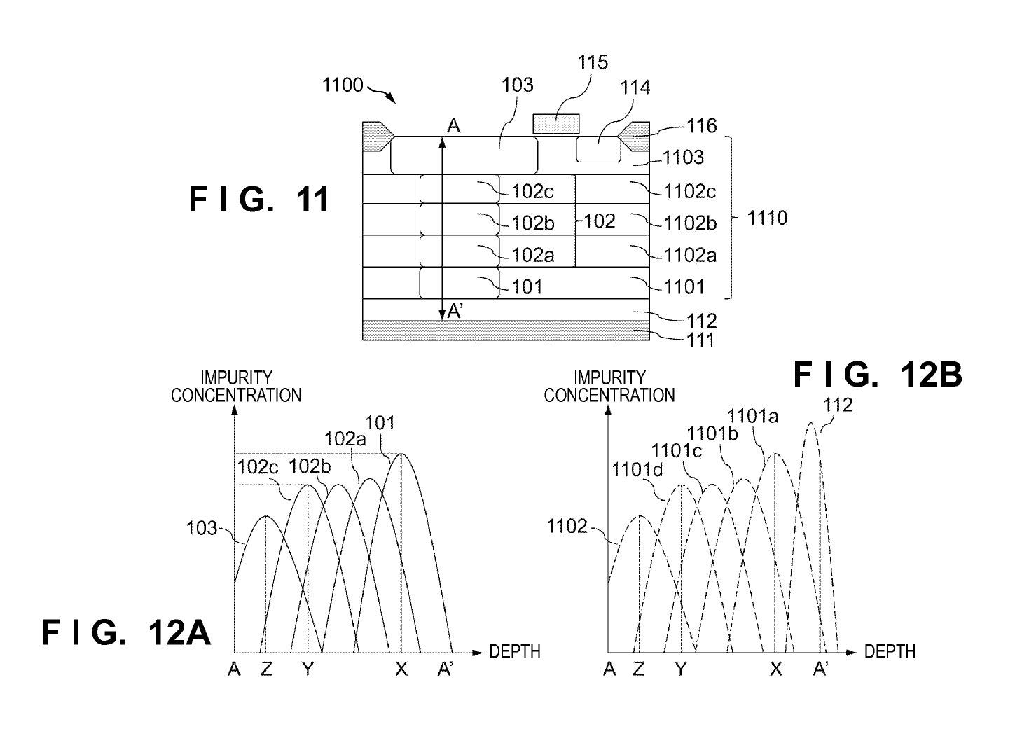

The structure and manufacturing method of a solid-state image sensor 1100 according to a fifth embodiment will be explained with reference to FIGS. 11, 12A, and 12B. FIG. 11 is a sectional view schematically showing an arrangement example of a photoelectric converter formed in one pixel of the solid-state image sensor 1100 according to the fifth embodiment of the present invention. The difference of the solid-state image sensor 1100 according to this embodiment shown in FIG. 11 from the solid-state image sensor 900 according to the fourth embodiment is the arrangement of a well layer. This difference of the solid-state image sensor 1100 is that a well layer 1110 including well layers 1101, 1102a, 1102b, 1102c, and 1103 is formed instead of the well layer 113 of the solid-state image sensor 900, and the rest of the arrangement can be the same. Therefore, a repetitive explanation of the same constituent elements as those of the solid-state image sensor 900 will be omitted.

A method of manufacturing the photoelectric converter formed in one pixel of the solid-state image sensor 1100 will now be explained. The well layer 1110 of the solid-state image sensor 1100 is formed by implanting an impurity while changing the implantation energy. The well layer 1110 is so formed that the impurity concentration of each region is constant or the impurity concentration is higher in a deeper region of the substrate. Impurity implantation is performed such that a charge accumulation region 101 formed in the deepest position has the highest impurity concentration in a charge accumulation portion, and a charge accumulation region 103 formed in the shallowest position has the lowest impurity concentration, in this embodiment as well. Other steps can be same as those of the solid-state image sensor 900. Also, the present invention is not limited to this manufacturing method, and the constituent elements of the photoelectric converter of the solid-state image sensor of this embodiment need only be formed. Furthermore, in this embodiment, a charge accumulation region 102 has three impurity concentration peaks and the well layer 1110 has five impurity concentration peaks when an impurity is implanted, but the numbers of peaks are not limited to these values. For example, the number of impurity concentration peaks in the charge accumulation region 102 may also be two or less, or four or more. In addition, the number of impurity concentration peaks in the well layer 1110 may also be four or less, or six or more. That is, it is possible to appropriately design the peaks.

FIGS. 12A and 12B show concentration distributions in an A-A′ section of the solid-state image sensor 1100 shown in FIG. 11 when n- and p-type impurities are implanted. As shown in FIG. 12A, the n-type impurity region forms an impurity concentration distribution similar to that of the solid-state image sensor 900 shown in FIG. 10A. Meanwhile, the p-type impurity region also has a plurality of impurity concentration peaks as shown in FIG. 12B. If the well layer 1110 has an impurity concentration gradient as in this embodiment, a gradient capable of effectively collecting a signal charge from a deep region in a semiconductor substrate 111 toward the surface is formed. Also, the impurity concentration of the lowermost charge accumulation region 101 is made higher than those of the charge accumulation regions 102 and 103, in this embodiment as well. This makes it possible to form a region having a large potential difference to a deep position in the semiconductor substrate 111, and form a high potential barrier in the deep position. Accordingly, the same effects as those of the solid-state image sensor 900 described above are obtained by the solid-state image sensor of this embodiment as well.

Furthermore, in this embodiment, the implantation energy can be determined such that the impurity concentration peak positions in the charge accumulation regions 101, 102, and 103 and the impurity concentration peak position in the well layer 1110 have the same depth. Also, in each charge accumulation region and each well layer, an impurity concentration peak distribution can be formed such that the heights of the impurity concentration peaks in the upper and lower layers of the charge accumulation region and the heights of the impurity concentration peaks in the upper and lower layers of the well layer change in the same manner. By thus appropriately determining the impurity concentration peak depth and distribution, it is possible to effectively enhance the charge accumulation capacity. Consequently, the saturated charge quantity can further be increased. In addition, at least one of the impurity concentration peaks in the charge accumulation regions 101, 102, and 103 can have the same depth as that of the impurity concentration peak in the well layer 1110. Furthermore, all of the impurity concentration peaks in the charge accumulation regions 101, 102, and 103 can have the same depth as that of the impurity concentration peak in the well layer 1110. The charge accumulation portion and well layer may also have the same impurity concentration peak position and the same impurity concentration distribution.

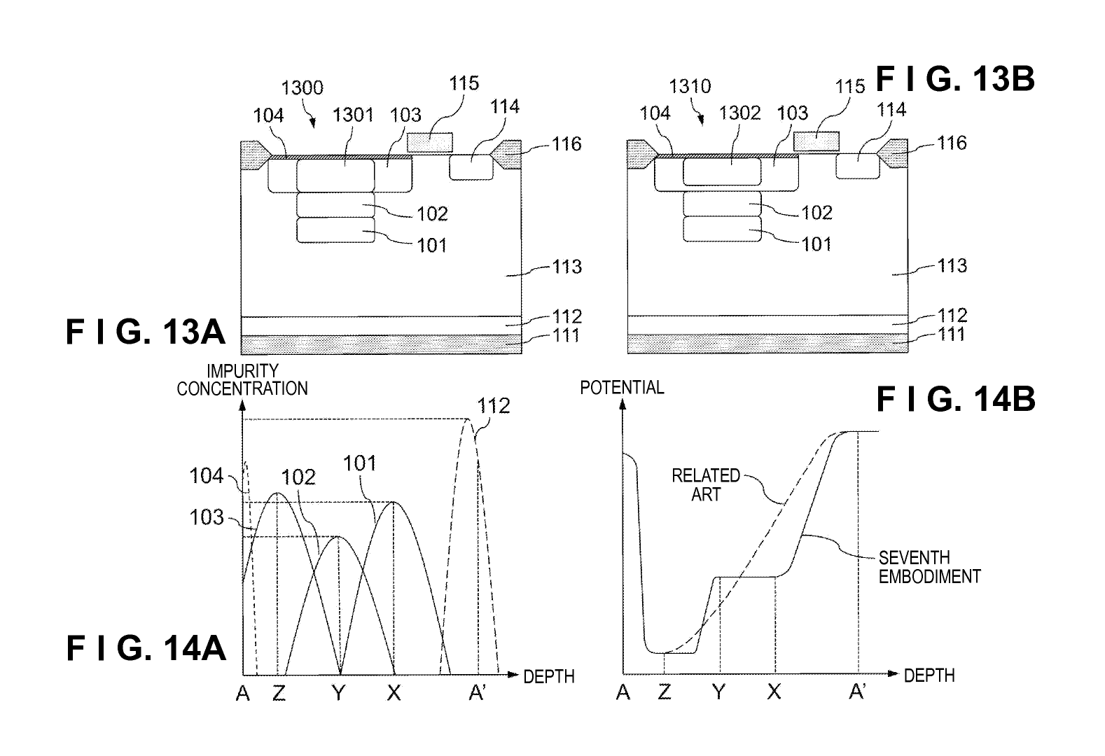

The structure and manufacturing method of a solid-state image sensor 1300 according to a sixth embodiment of the present invention will be explained with reference to FIGS. 13A and 13B. FIGS. 13A and 13B are sectional views schematically showing arrangement examples of a photoelectric converter formed in one pixel of the solid-state image sensor 1300 according to the sixth embodiment of the present invention. Referring to FIG. 13A, the solid-state image sensor 1300 according to this embodiment differs from the solid-state image sensor 600 according to the second embodiment in that a charge accumulation region 103 in the shallowest position includes an impurity region 1301, and the rest of the arrangement is the same. Therefore, a repetitive explanation of the same constituent elements as those of the solid-state image sensor 600 will be omitted. The impurity region 1301 can be a fourth semiconductor region of a p-type impurity region. The impurity region 1301 can also be a fifth semiconductor region of an n-type impurity region having an impurity concentration lower than that of the charge accumulation region 103.

A method of manufacturing the photoelectric converter formed in one pixel of the solid-state image sensor 1300 will now be explained. The impurity region 1301 of the solid-state image sensor 1300 is formed by implanting a p-type impurity by using, for example, the same mask pattern 202 after implanting an impurity for charge accumulation regions 101 and 102 shown in FIGS. 2E and 2F. If the concentration at which this p-type impurity is implanted is higher than the concentration of the impurity in the charge accumulation region 103, the impurity region 1301 is a p-type impurity region. If the concentration at which this p-type impurity is implanted is lower than the concentration of the n-type impurity in the charge accumulation region 103, the impurity region 1301 is an n-type impurity region having an impurity concentration lower than that of the charge accumulation region 103. In this embodiment, the impurity region 1301 may not spread in the whole charge accumulation region 103 in the depth direction, and may not be in contact with the charge accumulation region 102. This impurity region may also be shallower than the charge accumulation region 103 in the depth direction, like an impurity region 1302 of a solid-state image sensor 1310 shown in FIG. 13B. The dimensions in the depth direction of the impurity regions 1301 and 1302 of the solid-state image sensors 1300 and 1310 can be determined by properly selecting the impurity implantation energy. Other steps can be the same as those of the solid-state image sensor 600. Also, the present invention is not limited to this manufacturing method, and the constituent elements of the photoelectric converter of the solid-state image sensor of this embodiment need only be formed.

A region having a large potential difference can be formed to a deep position in a semiconductor substrate 111 by making the impurity concentration of the charge accumulation region 101 in the deepest position higher than those of the charge accumulation regions 102 and 103, in this embodiment as well. It is also possible to form a high potential barrier in the deep position of the semiconductor substrate 111. Accordingly, the same effects as those of the solid-state image sensor 600 described above are obtained by the solid-state image sensor 1300 as well.

In addition, in this embodiment, a region where the charge accumulation region 103 overlaps the charge accumulation regions 101 and 102 can be decreased by forming the impurity regions 1301 and 1302. Alternatively, the charge accumulation region 103 does not overlap the charge accumulation regions 101 and 102. This arrangement can decrease a high-impurity-concentration region in the charge accumulation region. When transferring a signal charge from the charge accumulation region, therefore a potential pocket which can be formed in a high-impurity-concentration region is hardly formed. As a consequence, the transfer efficiency can be increased.

Also, a depletion layer from a well layer 113 hardly reaches the charge accumulation region 103 formed on the charge accumulation regions 101 and 102. If the impurity regions 1301 and 1302 are p-type impurity regions, the charge accumulation regions 101, 102, and 103 can easily be depleted. When transferring a signal charge, therefore, the charge accumulation regions 101, 102, and 103 can be depleted at a lower voltage. Consequently, the transfer efficiency can be increased.

Furthermore, in the solid-state image sensor 1310, the charge accumulation regions 102 and 103 are n-type charge accumulation regions which continue to each other. However, a p-type impurity region may also be formed between the charge accumulation regions 102 and 103. If the charge accumulation regions 102 and 103 are depleted, this p-type impurity region is also depleted, thereby electrically connecting the charge accumulation regions 102 and 103.

The structure and manufacturing method of a solid-state image sensor according to a seventh embodiment of the present invention will be explained with reference to FIGS. 14A and 14B. The solid-state image sensor according to this embodiment differs from the solid-state image sensor 600 according to the second embodiment in that the impurity concentration of a charge accumulation region 103 in the shallowest position is made higher than that of a charge accumulation region 101 in the deepest position. The rest of the arrangement can be the same as that of the solid-state image sensor 600. Therefore, the sectional structure of the solid-state image sensor of this embodiment is the same as that of the solid-state image sensor 600. Accordingly, a repetitive explanation of the same constituent elements will be omitted.

A method of manufacturing a photoelectric converter formed in one pixel of the solid-state image sensor of this embodiment will now be explained. The solid-state image sensor of this embodiment can be the same as the solid-state image sensor 600 except for the impurity implantation conditions of the charge accumulation regions 101, 102, and 103. Implantation for forming the charge accumulation regions 101, 102, and 103 is performed under, for example, the following conditions. To form the charge accumulation region 103, implantation is performed by using an implantation energy of 500 keV such that the impurity concentration is 2×10¹⁷ cm⁻³. To form the charge accumulation region 102, implantation is performed by using an implantation energy of 600 keV such that the impurity concentration is 2×10¹⁶ cm⁻³. To form the charge accumulation region 101, implantation is performed by using an implantation energy of 700 keV such that the impurity concentration is 1×10¹⁷ cm⁻³ in a charge accumulation region in the deepest position. In this embodiment as described above, impurity implantation is so performed that the impurity concentration of the charge accumulation region 103 in the shallowest position is highest among the charge accumulation regions 101, 102, and 103. Also, impurity implantation is so performed that the impurity concentration of the charge accumulation region 101 formed in the deepest position among the charge accumulation regions 101 and 102 except for the charge accumulation region 103 in the shallowest position is highest. Other steps can be the same as those of the solid-state image sensor 600. In this embodiment, the concentration of a p-type impurity in an impurity region 104 on the substrate surface can be higher than that of an n-type impurity in the charge accumulation region 103. The impurity region 104 forms a potential barrier, and suppresses the generation of a dark current by spacing the charge accumulation region apart from the substrate surface. Furthermore, the present invention is not limited to this manufacturing method, and the constituent elements of the photoelectric converter of the solid-state image sensor of this embodiment need only be formed.

FIGS. 14A and 14B show an impurity concentration distribution and potential distribution in an A-A′ section of the solid-state image sensor of this embodiment having the same structure as that of the solid-state image sensor 600 shown in FIG. 6. As shown in FIG. 14A, the impurity concentration of the charge accumulation region 103 is highest compared to the impurity concentrations of other charge accumulation regions. Also, of the charge accumulation regions except for the charge accumulation region 103, the impurity concentration of the charge accumulation region 101 formed in the deepest position is higher than that of the charge accumulation region 102. As indicated by the potential distribution shown in FIG. 14B, therefore, a potential difference is formed between the uppermost charge accumulation region 103 close to the substrate surface and the charge accumulation region 102.

By thus making the impurity concentration of the charge accumulation region 103 higher than that of the charge accumulation region 102, an effect of transferring a signal charge accumulated in the charge accumulation regions 101 and 102 as deep regions in the semiconductor substrate 111 to the substrate surface within a short time is obtained. Also, the impurity concentration of the charge accumulation region 101 in the deepest position is made higher than that of the charge accumulation region 102, in this embodiment as well. This makes it possible to form a region having a large potential difference to a deep position in the semiconductor substrate 111, thereby forming a high potential barrier in the deep position. Accordingly, the same effects as those of the solid-state image sensor 600 described above can be obtained by the solid-state image sensor of this embodiment as well. Furthermore, the effect of transferring a signal charge accumulated in the deep region of the semiconductor substrate 111 to the substrate surface within a short time is obtained.

The seven embodiments according to the present invention have been explained above, but the present invention is not limited to these embodiments. The above-described embodiments can appropriately be changed and combined.

As an application example of the solid-state image sensor according to each of the above-mentioned embodiments, a camera incorporating the solid-state image sensor will be explained below. The concept of the camera includes not only an apparatus whose main purpose is image sensing, but also an apparatus having an image sensing function as an auxiliary function (for example, a personal computer or portable terminal). The camera may also be a module component such as a camera head. The camera includes the solid-state image sensor according to the present invention exemplified as the above-mentioned embodiment, and a signal processing unit for processing an output signal from the solid-state image sensor. This signal processing unit can include a processor for processing digital data based on the signal obtained from the solid-state image sensor. An A/D converter for generating this digital data can be formed on the semiconductor substrate of the solid-state image sensor, and can also be formed on another semiconductor substrate.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application Nos. 2014-176219, filed Aug. 29, 2014, and 2015-061665, filed Mar. 24, 2015, which are hereby incorporated by reference wherein in their entirety.

What is claimed is:

1. A solid-state image sensor comprising:
a substrate including a semiconductor region having a first conductivity type, and a charge accumulation portion having a second conductivity type opposite to the first conductivity type and configured to accumulate an electric charge generated by photoelectric conversion,
wherein the semiconductor region includes a first semiconductor region, and a second semiconductor region formed below the first semiconductor region and having an impurity concentration higher than that of the first semiconductor region,
the charge accumulation portion has a side and a bottom covered with the semiconductor region, and includes at least three regions arranged along a depth direction of the substrate,
a first region formed in a shallowest position of the at least three regions has a width larger than that of each of the at least three regions except for the first region, in a direction parallel to a surface of the substrate, and
an impurity concentration of a second region formed in a deepest position of the at least three regions is higher than that of each region between the first region and the second region of the at least three regions.

2. The sensor according to claim 1, wherein an impurity concentration of each of the at least three regions except for the first region is not less than that of a region formed on the each region.

3. The sensor according to claim 1, wherein the at least three regions include a region having an impurity concentration lower than that of the first region, between the first region and the second region.

4. The sensor according to claim 1, wherein the impurity concentration of the second region is higher than that of the first region.

5. The sensor according to claim 1, wherein the impurity concentration of the first region is higher than that of each of the at least three regions except for the first region.

6. The sensor according to claim 1, wherein a potential distribution formed in the charge accumulation portion in the depth direction of the substrate includes a constant portion between the first region and the second region.

7. The sensor according to claim 1, wherein a width of the second region is smaller than that of each of the at least three regions except for the second region.

8. The sensor according to claim 1, wherein at least one of the at least three regions has an impurity concentration peak in the same depth as that of an impurity concentration peak position of the first semiconductor region.

9. The sensor according to claim 8, wherein
the first semiconductor region includes regions equal in number to the at least three regions in the depth direction of the substrate, and
each of the at least three regions has an impurity concentration peak in the same depth as that of an impurity concentration peak of any of the regions of the first semiconductor region, which are equal in number to the at least three regions.

10. The sensor according to claim 9, wherein an impurity concentration distribution at an impurity concentration peak position of the at least three regions are equal to an impurity concentration distribution at an impurity concentration peak position of the regions of the first semiconductor region, which are equal in number to the at least three regions.

11. The sensor according to claim 1, wherein
the at least three regions include a third region, and a fourth region formed on the third region, between the first region and the second region, and
an impurity concentration of the third region is not less than that of the fourth region.

12. The sensor according to claim 1, wherein the substrate further includes a third semiconductor region having the first conductivity type on the charge accumulation portion.

13. The sensor according to claim 12, wherein an impurity concentration of the third semiconductor region is higher than that of the first region.

14. The sensor according to claim 1, wherein the substrate further includes a fourth semiconductor region having the first conductivity type and surrounded by the first region.

15. The sensor according to claim 1, wherein
the substrate further includes a fifth semiconductor region having the second conductivity type and surrounded by the first region, and
an impurity concentration of the fifth semiconductor region is lower than that of the first region.

16. A solid-state image sensor comprising:
a substrate including a semiconductor region having a first conductivity type, and a charge accumulation portion brought into contact with the semiconductor region, having a second conductivity type opposite to the first conductivity type, and configured to accumulate an electric charge generated by photoelectric conversion,
wherein an impurity concentration distribution of the semiconductor region in a depth direction of the substrate includes a first part, and a second part below the first part and having an impurity concentration higher than that of the first part,
an impurity concentration distribution of the charge accumulation portion in the depth direction has at least three peaks, and
an impurity concentration of a peak in a deepest position of the at least three peaks is higher than that of one of the at least three peaks except for a peak in a shallowest position and the peak in the deepest position.

17. A solid-state image sensor comprising:
a substrate including a semiconductor region having a first conductivity type, and a charge accumulation portion having a second conductivity type opposite to the first conductivity type and configured to accumulate an electric charge generated by photoelectric conversion,
wherein the semiconductor region includes a first semiconductor region, and a second semiconductor region formed below the first semiconductor region and having an impurity concentration higher than that of the first semiconductor region,
the charge accumulation portion includes at least a first region and a second region arranged in this order from a surface of the substrate along a depth direction of the substrate, and a third region formed between the first region and the second region,
the first region has a width larger than those of the second region and the third region in a direction parallel to the surface, and
an impurity concentration of the second region is higher than that of the third region.

18. A solid-state image sensor comprising:
a substrate including a semiconductor region having a first conductivity type, and a charge accumulation portion having a second conductivity type opposite to the first conductivity type and configured to accumulate an electric charge generated by photoelectric conversion,
wherein an impurity concentration of the semiconductor region at a first part of the semiconductor region is lower than an impurity concentration of the semiconductor region at a second part of the semiconductor region, the second part being provided below the first part,
a first length of the charge accumulation portion along a first line which is parallel to a surface of the substrate and is passing at a first point within the charge accumulation portion is longer than a second length of the charge accumulation portion along a second line which is parallel to the surface and is passing at a second point within the charge accumulation portion and than a third length of the charge accumulation portion along a third line which is parallel to the surface and is passing at a third point within the charge accumulation portion,
the first point, the third point and the second point are arranged along a depth direction in this order from the surface, and
an impurity concentration of the charge accumulation portion at the second point is higher than an impurity concentration of the accumulation portion at the third point.

19. A camera comprising:
a solid-state image sensor and a signal processing unit, wherein
the solid-state image sensor comprises a substrate including a semiconductor region having a first conductivity type, and a charge accumulation portion having a second conductivity type opposite to the first conductivity type and configured to accumulate an electric charge generated by photoelectric conversion,
the semiconductor region includes a first semiconductor region, and a second semiconductor region formed below the first semiconductor region and having an impurity concentration higher than that of the first semiconductor region,
the charge accumulation portion has a side and a bottom covered with the semiconductor region, and includes at least three regions arranged along a depth direction of the substrate,
a first region formed in a shallowest position of the at least three regions has a width larger than that of each of the at least three regions except for the first region, in a direction parallel to a surface of the substrate,
an impurity concentration of a second region formed in a deepest position of the at least three regions is higher than that of each region between the first region and the second region of the at least three regions; and
the signal processing unit configured to process a signal obtained by the solid-state image sensor.
